(19) United States
(12) Patent Application Publication
(10) Pub. No.: US 2012/0092390 A1
(43) Pub. Date: Apr. 19, 2012

(54) Low Power Image Intensifier Device Comprising Black Silicon Detector Element

(76) Inventors: David Ludwig, Irvine, CA (US); John Carson, Corona del Mar, CA (US)

(21) Appl. No.: 13/272,341

(22) Filed: Oct. 13, 2011

Related U.S. Application Data
(60) Provisional application No. 61/455,126, filed on Oct. 13, 2010.

(51) Int. Cl. G09G 5/10; H01L 33/00

(52) U.S. Cl. 345/690; 257/84; 257/E33.001

(57) ABSTRACT

A detector module which may comprise a black silicon detector for detecting incident radiation and generating a visible output to a display output pixel element such as one or more OLED elements. One or more vertically interconnected unit cells, which may be in the form of a plurality of vertically stacked and bonded layers, is disclosed having a detector layer comprising one or more black silicon detector elements, an amplification layer and a display layer having a dedicated display output pixel element. The layers are vertically interconnected by means of electrically conductive area interconnects such as electrically conductive through-silicon vias.

### CROSS-REFERENCE TO RELATED APPLICATIONS

This application claims the benefit of U.S. Provisional Patent Application No. 61/455,126, filed on Oct. 13, 2010 entitled “Low Power Camera” pursuant to 35 USC 119, which application is incorporated fully herein by reference.

### STATEMENT REGARDING FEDERALLY SPONSORED RESEARCH AND DEVELOPMENT

N/A

### BACKGROUND OF THE INVENTION

1. Field of the Invention

The invention relates generally to the field of imaging and image intensification devices.

More specifically, the invention relates to low power, high resolution image intensifier device comprising, in one embodiment, one or more black silicon detector pixel elements each having a dedicated display output pixel element for use in low light environments.

2. Description of the Related Art

Image intensifiers (sometimes referred to as “I2”) are used to amplify ambient light such as moonlight or starlight in order to provide a useable visible image for a user.

Existing image intensifier devices operate by receiving photons from an observed scene, such as through an objective lens, and converting the received photons into electrons by a photocathode tube in the image intensifier device.

The resulting electron output from the photocathode tube is limited and is unusable in existing image intensifier devices. The relatively few electrons generated by the photocathode are then accelerated in an electric field and multiplied by the use of a micro-channel plate (MCP) assembly. In a micro-channel plate, an electron entering an individual micro-channel strikes the channel wall and generates a cascade of electrons, which in turn, strike the channel wall and create yet a larger cascade of electrons. Subsequently, the amplified cascade of electrons strikes a phosphor screen in the prior art device and a visible image is created.

The relatively few electrons that are generated as the result of the received photons from the photocathode are effectively “amplified” using the micro-channel plate, and then converted back to photons so as to form a visible image on a display.

Unfortunately, prior art image intensifier devices are expensive, bulky, relatively heavy and complex due to the fact these prior art devices must incorporate an expensive and fragile micro-channel plate and photocathode to convert the photons from a scene into electrons and to amplify the electrons from the photocathode to a useable level. The above constraints in the prior art have limited the development of smaller and less expensive image intensifier devices.

The United States military has stated that it seeks improved image intensifier devices for use in both military and civilian applications.

For instance, in Small Business Innovation Research Proposal Topic No. AF06-022, “Next Generation Architecture for Night Vision Imaging”, the proposal topic states, in relevant part:

“Image intensifier (I2) tubes are commonly used in head-mounted devices that are designed to aid vision at night. I2 tubes are analog devices that integrate the sensor, light amplifier, and display. The amplifier within the I2 tube is a microchannel plate, which must be suspended in a vacuum, thereby complicating fabrication and permitting certain image defects. Many I2 tubes employ a coherent fiber optic bundle to re-invert the image after amplification, adding weight, size, and complexity. Further, I2 tubes do not lend themselves to the use of digital image enhancement techniques or the display of images produced by outboard sensors or computers.”

What is needed is an image intensifier device that is less costly, consumes less power, is not prone to image burn and is lighter and more rugged than prior art image intensifier devices.

### BRIEF SUMMARY OF THE INVENTION

The invention generally comprises a detector pixel element which may comprise a black silicon detector element for detecting incident radiation and for generating a proportional response in the form of an electrical output signal which is amplified and displayed to a user.

In a first aspect of the invention, a vertically interconnected unit cell is disclosed comprising a detector layer element having a detector input and a detector output. The detector layer comprises a detector pixel element that may be a black silicon detector element. The unit cell may comprise an amplification layer element having an amplification input and an amplification output and a display layer element having a display input and a display output and is configured so that the detector pixel element has a dedicated display output pixel element.

In a second aspect of the invention, the unit cell further comprises an electrically 13 conductive area interconnect disposed between and in electrical connection with the output of at least one layer element and the input of at least one other respective layer element.

In yet a third aspect of the invention, the display layer element of the unit cell comprises an OLED or micro-display element.

In yet a fourth aspect of the invention, the amplification layer element of the unit cell comprises an analog preamplifier layer element and an analog display amplifier layer element.

In yet a fifth aspect of the invention, the area interconnect of the unit cell comprises an electrically conductive through-silicon via.

In yet a sixth aspect of the invention, a stacked microelectronic module is disclosed and is comprised of a plurality of vertically interconnected unit cells, each unit cell comprising detector layer element comprising a black silicon detector pixel element having a detector input and a detector output, an amplification layer element having an amplification input and an amplification output and a display layer element having a display input and a display output wherein at least one black silicon detector pixel element has a dedicated display output pixel element.

In yet a seventh aspect of the invention, the module further comprises an electrically conductive area interconnect disposed between and in electrical connection with the output of at least one layer element and the input of at least one other respective layer element.

In yet an eighth aspect of the invention, the display layer element of the module comprises an OLED or micro-display element.

In yet a ninth aspect of the invention, the amplification layer element of the module comprises an analog preamplifier layer element and an analog display amplifier layer element.

In yet a tenth aspect of the invention, the area interconnect of the module comprises an electrically conductive through-silicon via.

In yet an eleventh aspect of the invention, a method for image intensification is disclosed comprising the steps of generating an output signal from a detector pixel element in response to incident radiation on the input of the detector pixel element, receiving the output signal at an amplifier input by means of an electrically conductive area interconnect, amplifying the output signal to define an amplified output signal and receiving the amplified output signal at a display input by means of an electrically conductive area interconnect and generating an output to a dedicated display output pixel element.

In yet a twelfth aspect of the invention the electrically conductive area interconnect of the method comprises an electrically conductive through-silicon via.

These and various additional aspects, embodiments and advantages of the present invention will become immediately apparent to those of ordinary skill in the art upon review of the Detailed Description and any claims to follow.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE SEVERAL VIEWS OF THE DRAWINGS

FIG. 1 depicts a microphotograph of the individual silicon elements of the input surface of a black silicon detector.

FIG. 2 illustrates a block diagram of the major layers and elements of the unit cell and module of the invention.

FIG. 3 illustrates the steps of the method of the invention.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

Turning now to the figures wherein like references define like elements among the several views, Applicant discloses a low power, high resolution image intensification device for use in low-light environments.

The stacked module of the invention provides high signal gain in the detector and very low noise electronics without the need for multiplexing the detector signal to provide a compact low-light imaging device. The invention provides a low-light sensor solution that competes with night vision goggles but does not require use of a fragile and expensive photocathode or micro-channel plate.

In one embodiment, the detector of the invention is fabricated from black silicon, that is, silicon that has been bombarded by a high-power laser or energy source in the presence of an etching atmosphere. Black silicon material may be fabricated using a reactive ion etching process or “RIE”. An alternative fabrication method for black silicon is currently being developed and commercialized by SiOnyx, Inc. of Massachusetts.

The silicon “spikes” that comprise black silicon are depicted in FIG. 1 and result in a signal gain that is reported as high as 200 to 300 due in part to their high surface area and relatively high photon absorption. The individual black silicon elements are needle-shaped structures typically having a height of about 10 microns and a diameter of less than about one micron.

Black silicon has a unique electrical property in that when subject to an electrical bias, an incident photon on an individual black silicon spike generates multiple tens of electrons as a result. Because of the small feature size and density of the individual black silicon spikes when used as a detector element, this unique electrical property makes black silicon particularly suitable for use as an image intensification detector in that it mimics the behavior of a photocathode/microchannel plate assembly.

Examples of suitable black silicon detector materials for use with the detectors of the invention are disclosed in U.S. Pub. No. US2008/0258604, “Systems and Methods for Light Absorption and Field Emission Using Microstructured Silicon” to Mazur et al., and U.S. Pub. No. US2003/0029496, “Systems and Methods for Light Absorption and Field Emission Using Microstructured Silicon” to Mazur et al., the entirely of each publication of which is incorporated herein by reference.

The general principal behind the invention is “photons in and photons out” with gain between. The device operates in similar manner to how a human sees photons through an eyepiece since the OLED or equivalent display element of the invention is substantially the same size as the associated detector array.

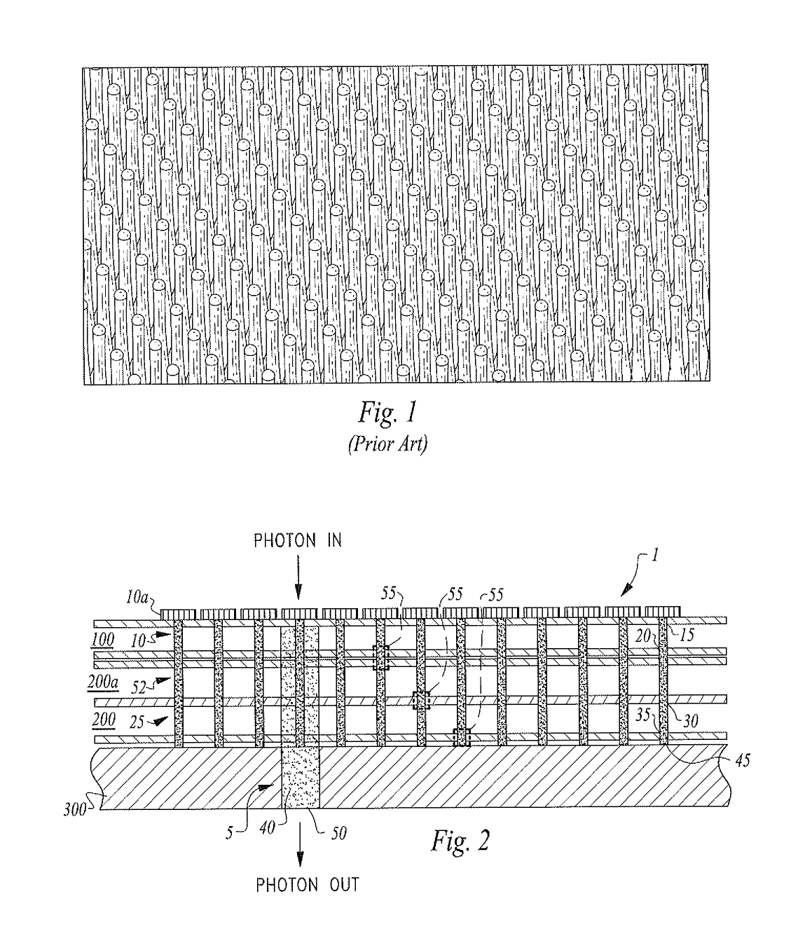

FIG. 2 is a block level depiction of the low power, low light solid state image intensifier device 1 of the invention.

As illustrated in FIG. 2, a stacked microelectronic module is provided comprising a plurality of vertically interconnected unit cells 5. Each unit cell 5 may comprise a detector layer element 10 which, in one embodiment, further comprises a black silicon detector pixel element 10a and has a detector input 15 and a detector output 20. Detector layer element 10 comprises electronic circuitry for processing the output signal of detector pixel element 10a.

It is expressly noted that detector pixel element 10a is not limited to a black silicon detector pixel element and may comprise any suitable detector pixel element for detecting electromagnetic radiation in a predetermined spectrum and producing a proportional electrical signal in response thereto.

Detector pixel element 10a may be in the form of a detector pixel on a focal plane array (“FPA”) of individual detector pixel elements in a two-dimensional array. The detector pixel elements 10a may comprise, without limitation, a microbolometer detector pixel element comprised of a vanadium oxide, amorphous silicon material or other IR radiation detector material, a CMOS imager detector pixel element, a silicon-based or silicon diode detector pixel element or any equivalent detector pixel element.

Each unit cell 5 may comprise an amplification layer element 25 having an amplification input 30 and an amplification output 35.

Each unit cell may comprise a display layer element 40 having a display input 45 and a display output pixel element 50 such as a micro-display pixel element in the form of an OLED, P-LED, micro-emissive display, LCD display or equivalent display or micro-display element.

In a preferred embodiment of the invention, each detector pixel element 10a has a dedicated detector layer element 10, a dedicated amplification layer element 25 and a dedicated output display pixel element 50 such that the output of detector pixel element 10a is displayed to its dedicated output display pixel element 50 without the need for multiplexing the associated signal, i.e., photons in, gain, photons out.

The ability to avoid multiplexing the detector pixel element signal is due, in part to the use of stacked, densely area interconnected layers of dedicated detector support electronics in the module, saving power and space in the device.

The low overall power consumption of the device of the invention results in part from the fact the signals in the device are not required to be digitized or multiplexed.

The amplifier layer element 25 of invention may comprise analog electronics pre-amplifier circuitry, filter circuitry, analog electronics amplification circuitry, post-amplification or processing circuitry or a combination of each of these in the form of a preamplifier layer element 52 disposed between the detector layer element 10 and amplifier layer element 25.

A preamplifier layer element may desirably be included to boost the detector's output signal strength without significantly degrading the signal-to-noise ratio (SNR) and to act as an impedance buffer.

The detector, electronics and display layer elements are preferably fabricated in stacked layers as mosaic-type structures having a predetermined number of detector pixel elements 10a in each mosaic. The layer-to-layer area interconnection of the invention permits the detector signal to flow to a dedicated display output pixel element 50 without multiplexing. This desirably eliminates the need for associated multiplexing circuitry and maintains small overall circuit size and provides a device wherein the detector pixel array has about the same “footprint” as the display output pixel element array.

The embodiment of FIG. 2 illustrates a multi-layer module comprising a stack of layers, each comprising predetermined circuit elements that define individual unit cells. The unit cell elements in the different layers are interconnected using electrically conductive area interconnect structures 55.

The layers in the module may comprise a detector layer 100 comprising a plurality of detector layer elements 10, and an amplification layer 200 comprising a plurality of amplification layer elements 25.

The invention may further comprise a preamplification layer 200a comprised of a plurality of predetermined circuit elements for the processing of the detector signal in the form of a plurality of dedicated, individual preamplifier layer elements 52 in each unit cell 5 that is disposed between detector layer 100 and amplification layer 200.

The multilayer module further comprises a display layer 300 which, in the illustrated embodiment, comprises an OLED or LCD micro-display comprising a two-dimensional array of display output pixel elements 50 wherein each display pixel in the micro-display has a dedicated signal input in the form of a signal from a dedicated detector pixel element 10a.

The invention takes advantage the “pancake stacking” technology for IC layers developed and disclosed by Irvine Sensors Corporation, assignee of the instant application, in, for instance, U.S. Pat. No. 5,279,991, “Method for Fabricating Stacks of IC Chips by Segmenting a Larger Stack” to Minahan et al., U.S. Pat. No. 5,424,920, “Non-Conductive End Layer for Integrated Stack of IC Chips” to Miyake, and U.S. Pat. No. 5,688,721, “3D Stack of IC Chips Having Leads Reached by Vias Through Passivation Cover Access Plane” to Johnson.

In a preferred embodiment, the layer-to-layer area interconnect structures 55 are electrically conductive area interconnect structures in the form of electrically conductive through-hole or through-silicon vias. Suitable electrically conductive through-silicon via (“TSV”) structures are commercially available from Tru-Si Technologies, Inc.

In this embodiment, electrically conductive through-silicon vias are defined at predetermined locations such as by a dry reactive ion etching process or DRIE. The through-vias are plated or filled with a conductive material such as copper to create a feed-through structure comprising a first feed-through structure major surface and second feed-through structure-major surface, each with one or more exposed conductive vias (that is, first and second terminal ends) for electrical connection between the first feed-through structure major surface and second feed-through structure major surface.

The area interconnect structures 55 are not limited to the use of through-silicon vias and may comprise any suitable electrical area interconnect (i.e., “feed-through”) structure.

By way of example and not by limitation, area interconnect structures 55 may, in an alternative embodiment, comprise conductive metalized polymer columns formed using a solderable photoresist.

In a further alternative embodiment, the area interconnect structures 55 may comprise multiple stacked stud bumps defined at a predetermined pitch and height that have been encapsulated in a suitable dielectric material.

Examples of electrically conductive area interconnect structures 55 suitable for use in the invention are disclosed in, for instance U.S. Pat. No. 7,919,844, “Tier Structure with Tier Frame Having a Feedthrough Structure” to Ozguz, et al.

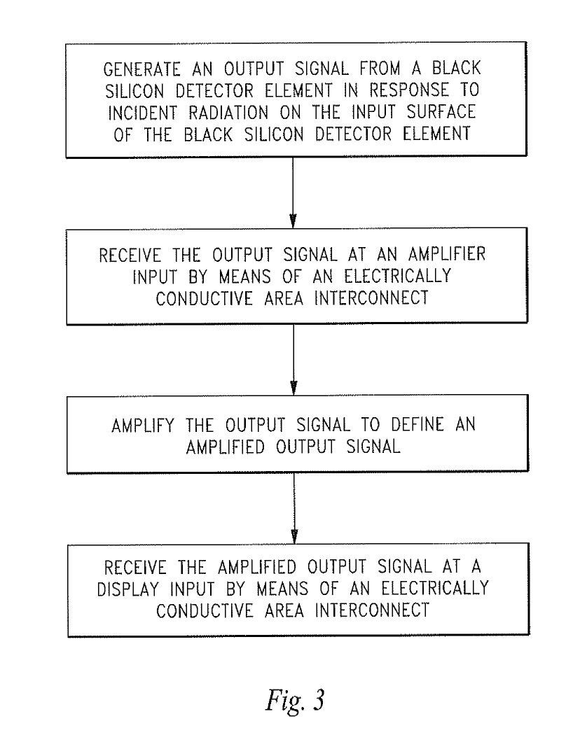

FIG. 3 illustrates a preferred set of steps of the method of the invention.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

We claim:

1. A vertically-interconnected unit cell comprising:
a detector layer element comprising a detector input and a detector output and comprising a detector pixel element,
an amplification layer element comprising an amplification input and an amplification output,
a display layer element comprising a display input and a display pixel output element, wherein the detector pixel element has a dedicated display output pixel element.

2. The device of claim 1 wherein the detector pixel element is a black silicon detector pixel element.

3. The device of claim 1 further comprising an electrically conductive area interconnect disposed between and in electrical connection with the output of at least one layer element and the input of at least one respective other layer element.

4. The device of claim 1 wherein the display layer element comprises an OLED pixel element.

5. The device of claim 1 wherein the amplification layer element comprises an analog preamplifier layer element and an analog display amplifier layer element.

6. The device of claim 3 wherein the area interconnect comprises an electrically conductive through-silicon via.

7. A stacked microelectronic module comprised of a plurality of vertically interconnected unit cells, each unit cell comprising:
a detector layer element comprising a detector input and a detector output and comprising a detector pixel element,
an amplification layer element comprising an amplification input and an amplification output, and,
a display layer element comprising a display input and a display output pixel element wherein at least one detector pixel element has a dedicated display output pixel element.

8. The device of claim 6 wherein the detector pixel element is a black silicon detector pixel element.

9. The device of claim 7 further comprising an electrically conductive area interconnect disposed between and in electrical connection with the output of at least one layer element and the input of at least one respective other layer element.

10. The device of claim 7 wherein the display layer element comprises an OLED pixel element.

11. The device of claim 7 wherein the amplification layer element comprises an analog preamplifier layer element and an analog display amplifier layer element.

12. The device of claim 8 wherein the area interconnect comprises an electrically conductive through-silicon via.

13. A method for image intensification comprising the steps of:
generating an electrical output signal from a detector pixel element in response to incident radiation on the input surface of the detector pixel element,
receiving the output signal at an amplifier input by means of an electrically conductive area interconnect,
amplifying the output signal to define an amplified output signal,
receiving the amplified output signal at a display input by means of an electrically conductive area interconnect and generating an output to a dedicated display output pixel element.

14. The method of claim 12 wherein the detector pixel element is a black silicon detector pixel element.

15. The method of claim 12 wherein the electrically conductive area interconnect comprises an electrically conductive through-silicon via.
